(19) United States
(12) Patent Application Publication
(10) Pub. No.: US 2005/0205923 A1
(43) Pub. Date: Sep. 22, 2005

(54) Non-volatile memory device having an asymmetrical gate dielectric layer and method of manufacturing the same

(76) Inventors: Jeong Hee Han, Suwon-si (KR); Soodoo Chae, Seongnam-si (KR); Sanghun Jeon, Yongin-si (KR)

Correspondence Address: LEE, STERBA & MORSE, P.C., SUITE 2000, 1101 WILSON BOULEVARD, ARLINGTON, VA, 22209, US

(21) Appl. No.: 11/084,106

(22) Filed: Mar. 21, 2005

(30) Foreign Application Priority Data
Mar. 19, 2004 (KR) 10-2004-0018748

(51) Int. Cl. H01L 29/788

(52) U.S. Cl. 257/315

(57) ABSTRACT

In a memory device, and a method of manufacturing the same, the memory device includes a semiconductor substrate, a first impurity region and a second impurity region formed by injecting impurities into the semiconductor substrate, and a gate structure on the semiconductor substrate between the first impurity region and the second impurity region, the gate structure including a gate electrode and an asymmetric dielectric layer including a floating gate.

### BACKGROUND OF THE INVENTION

1. Field of the Invention

The present invention relates to a non-volatile memory device having an asymmetrical gate dielectric layer. More particularly, the present invention relates to a non-volatile memory device, in which a thickness of a gate dielectric layer is varied to provide a high electron storing density with a low driving voltage difference, and a method of manufacturing the same.

2. Description of the Related Art

A data storing capacity of a semiconductor memory device changes proportionately with a number of memory cells, i.e., a degree of integration. A semiconductor memory device includes many memory cells, which are connected through circuits. A non-volatile memory device has improved features of low power consumption and excellent stability as compared to a conventional flash memory device. With the development in processing technology significant research has been performed to improve the degree of integration while preventing a decrease in aperture rate during processing. Accordingly, semiconductor memory devices having structures different from than of conventional semiconductor memory devices have been introduced.

A silicon-oxide-nitride-oxide-silicon (SONOS) memory device is a new memory device. Structures of conventional SONOS non-volatile memory devices are illustrated in FIGS. 1A and 1B. FIG. 1A illustrates a cross-sectional view of a conventional SONOS non-volatile memory device.

Referring to FIG. 1A, a first impurity region 12a and a second impurity region 12b, which are doped with impurities so that they have an opposite polarity from a semiconductor substrate 11, are formed on both sides of a semiconductor substrate 11. In this case, the first impurity region 12a is referred to as a source and the second impurity region is referred to as a drain. A channel region, which alone is in an insulating state, but through which electrons move when an external electric field is applied thereto, is formed between the source 12a and the drain 12b. A gate structure 13 is formed on the channel region between the source 12a and the drain 12b. A general gate structure 13 includes a gate dielectric layer and a gate electrode 17.

In the SONOS memory device as shown in FIG. 1A, the gate structure 13 includes a tunneling oxide layer 14, which is a first oxide layer, a floating gate 15, i.e., a nitride layer, a blocking oxide layer 16, which is a second oxide layer, and the gate electrode 17. In this case, the tunneling oxide layer 14 is in contact with the source 12a and the drain 12b and the floating gate 15 has a trap site with a predetermined density. FIG. 1B illustrates a cross-sectional view of a case in which the floating gate 15 is formed on only a portion of the tunneling oxide layer 14 in the memory device shown in FIG. 1A. More specifically, FIG. 1B illustrates a semiconductor device in which a SONOS memory is only partially formed.

The principle of storing information by driving such a SONOS memory device is as follows. When there is a voltage difference between the source 12a and the drain 12b and voltage higher than a threshold voltage (V_{threshold}) is applied to the gate electrode 17, an electric field reaches the channel region, which is positioned at a lower portion of the gate structure 13. In this case, electrons move to the channel region and these electrons become trapped in the trap site formed within the floating gate 15 on the tunneling oxide layer 14. The blocking oxide layer 16 prevents the electrons from moving to the gate electrode 17 in the process of becoming trapped in the floating gate 15.

Such a driving mechanism of a conventional non-volatile memory device has problems such as having a low electron storing efficiency and a high power consumption. This disadvantage will now be described in greater detail.

The current, which flows in the channel region of a conventional metal-oxide-semiconductor (MOS) device, changes in inverse proportion to a size of a perpendicular electric field with an increase of gate voltage. Therefore, to increase the amount of electrons flowing in the channel, when greater than the V_{threshold}, the gate voltage should be maintained to be low and the voltage applied to the impurities regions should be increased.

However, to increase the amount of electrons injected into the floating gate 15 of the memory device, the voltage applied to the impurities regions 12a and 12b should be lowered and the voltage applied to the gate should be increased. The solution to such a contradiction has not been presented so far and in reality, relatively high voltage is applied to both the gate structure 13 and impurities regions 12a and 12b. Therefore, problems such as relatively low electron injection efficiency exist since high consumption voltage is applied to drive the memory device.

### SUMMARY OF THE INVENTION

The present invention is therefore directed to a non-volatile memory device having an asymmetrical gate dielectric layer and a method of manufacturing the same, which substantially overcome one or more of the problems due to the limitations and disadvantages of the related art.

It is therefore a feature of an embodiment of the present invention to provide a memory device having excellent electron injection efficiency in a floating gate and low power consumption.

It is another feature of an embodiment of the present invention to provide a method of manufacturing such a non-volatile memory device.

At least one of the above and other features and advantages of the present invention may be realized by providing a memory device including a semiconductor substrate, a first impurity region and a second impurity region formed by injecting impurities into the semiconductor substrate, and a gate structure on the semiconductor substrate between the first impurity region and the second impurity region, the gate structure including a gate electrode and an asymmetric dielectric layer including a floating gate.

The memory device may further include at least two sub-channels between the first and second impurity regions.

The asymmetric dielectric layer may include a tunneling oxide layer on the semiconductor substrate between the first impurity region and the second impurity region, the floating gate on the tunneling oxide layer, and a blocking oxide layer on the floating gate. At least one of the tunneling oxide layer and the blocking oxide layer may have a varying thickness. The blocking oxide layer may include one or more steps formed therein.

The tunneling oxide layer may include silicon oxide (SiO₂).

The floating gate may include one selected from the group consisting of Si₂N₄, MO, MON, and MSiON, where M is metal. The metal may be selected from the group including hafnium (Hf), zirconium (Zr), tantalum (Ta), aluminum (Al) and one of the lanthanide group.

The blocking oxide layer may include one selected from the group including Al₂O₃ and SiO₂.

The gate electrode may include one selected from the group including polysilicon, a metal, and a metal compound.

The memory device may further include spacers on sidewalls of the gate structure.

At least one of the above and other features and advantages of the present invention may be realized by providing a method of manufacturing a memory device including forming a dielectric layer asymmetrically on a semiconductor substrate, forming a gate structure by forming a gate electrode on the dielectric layer, and removing side portions of the gate structure to expose portions of the semiconductor substrate on both sides of the gate structure, and forming a first impurity region to one side of the gate structure and a second impurity region to another side of the gate structure by injecting impurities into the exposed semiconductor substrate.

Forming the dielectric layer may include forming sequentially a tunneling oxide layer, a floating gate, and a blocking oxide layer on the semiconductor substrate.

Forming the tunneling oxide layer, the floating gate, and the blocking oxide layer may include forming at least one of the tunneling oxide layer and the blocking oxide layer to have a varying thickness. Forming the blocking oxide layer to have a varying thickness may include forming one or more steps in the blocking oxide layer.

The method may further include forming spacers on sidewalls of the gate structure and injecting impurities into the side portions of the semiconductor substrate, thereby forming third and fourth impurity regions having higher impurity densities than the first and second impurity regions, respectively.

Forming the dielectric layer asymmetrically may include forming at least two sub-channels between the first and second impurity regions.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIGS. 1A and 1B illustrate cross-sectional views of a conventional non-volatile memory device;

FIG. 2 illustrates a cross-sectional view of a non-volatile memory device according to an embodiment of the present invention;

FIGS. 3A through 3H illustrate cross-sectional views of stages in a method of manufacturing a non-volatile memory device according to an embodiment of the present invention;

FIGS. 4A through 4C illustrate the electric driving characteristics of a conventional memory device and a memory device according to an embodiment of the present invention.

### DETAILED DESCRIPTION OF THE INVENTION

Korean Patent Application No. 10-2004-0018748, filed on Mar. 19, 2004, in the Korean Intellectual Property Office, and entitled: “Non-Volatile Memory Device With Asymmetrical Gate Dielectric Layer and Method of Manufacturing the Same,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of films, layers and regions are exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

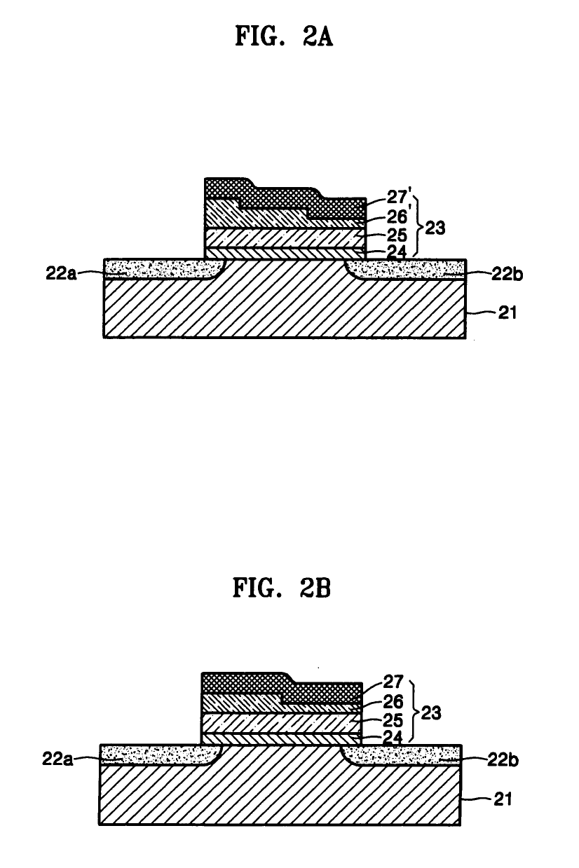

FIG. 2 illustrates a cross-sectional view of a non-volatile memory device according to an embodiment of the present invention.

Referring to FIG. 2, a semiconductor substrate 21 may be any substrate that is used in a general memory device, e.g., a p-type semiconductor substrate. First and second impurity regions, i.e., a source 22a and a drain 22b, are formed in upper regions of the semiconductor substrate 21. When the semiconductor substrate 21 is a p-type semiconductor substrate, the source 22a and the drain 22b are doped with n-type impurities. The source 22a and the drain 22b are separated by a predetermined distance and a channel is interposed therebetween.

A gate structure 23 is disposed on a region of the semiconductor substrate 21 between the source 22a and the drain 22b. The gate structure 23 is disposed on the channel and lower side portions of the gate structure 23 contact the source 22a and the drain 22b. The memory device may have a SONOS structure, in which the gate structure 23 includes a gate electrode 27 and a dielectric layer including a floating gate 25. In this case, the dielectric layer includes a tunneling oxide layer 24, the floating gate 25, e.g., a nitride layer, and a blocking oxide layer 26, which are stacked sequentially on the semiconductor substrate 21.

In the present embodiment, the blocking oxide layer 26 has at least one step. In this case, the tunneling oxide layer 24 may have a thickness less than a few millimeters. Although not illustrated, the tunneling oxide layer 24 may have a single step or a double step structure, and may be composed of silicon oxide.

The floating gate 25 may have a thickness less than approximately ten nanometers. The floating gate 25 may be composed of Si₃N₄, MO, MON, or MSiON, where M is a metal, e.g., hafnium (Hf), zirconium (Zr), tantalum (Ta), aluminum (Al) or one of the lanthanide group. The blocking oxide layer 26 is an insulating layer with a high dielectric constant and may be composed of SiO₂ or Al₂O₃. The blocking oxide layer 26 is formed to have at least one stepped portion. The gate electrode 27 formed on the blocking oxide layer 26 may be composed of an electrode material such as polysilicon, metal, or metal components.

Since the thickness of the dielectric layer of the gate structure 23 is not constant, two or more threshold voltages (V_{threshold}) can be obtained by the gate structure 23. This is a result of two or more sub-channels being formed between the source 22a and the drain 22b and means that two or more perpendicular electric fields can be produced by the gate electrode 27.

Due to the asymmetric nature of the dielectric layer due to the step structure thereof, the density of electrons that flow in a sub-channel disposed below a thicker portion of the blocking oxide layer 26 is greater than in another sub-channel disposed below a thinner portion of the blocking oxide layer 26. In addition, the density of electrons trapped in a portion of the floating gate 25 below the thinner portion of the blocking oxide layer 26 is greater than in the rest of the floating gate 25 due to the influence of a large perpendicular electrical field. In an alternative embodiment, two or more steps may be formed in the blocking oxide layer 26 and the height of the steps may be adjusted according to the number of the steps formed.

The operation of the memory device shown in FIG. 2 will now be described. A first predetermined gate voltage (V_{g}) is applied to the gate structure 23 through the gate electrode 27 and a first predetermined drain voltage V_{d} is applied to the drain 22b. When V_{g} is greater than V_{threshold}, electrons move to the channel region between the source 22a and the drain 22b. The electron density is proportional to the thickness of the thicker portion of the blocking oxide layer 26.

In addition, the density of electrons trapped in the floating gate 25 is proportional to the thickness of the thinner portion of the blocking oxide layer 26 resulting in an overall increase in the electron density trapped in the floating gate 25. Information is stored in this way and the stored information is read by applying a second predetermined gate voltage V_{g}′ (where V_{g}′<V_{g}) to the gate electrode 27 and applying a second predetermined drain voltage V_{d}′ (where V_{d}′<V_{d}) to the drain 22b and reading the current flowing through the channel.

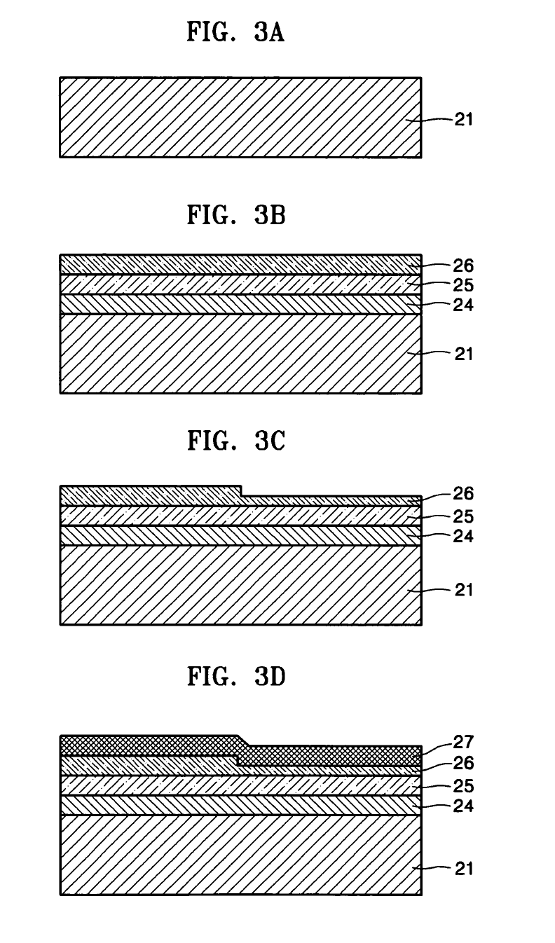

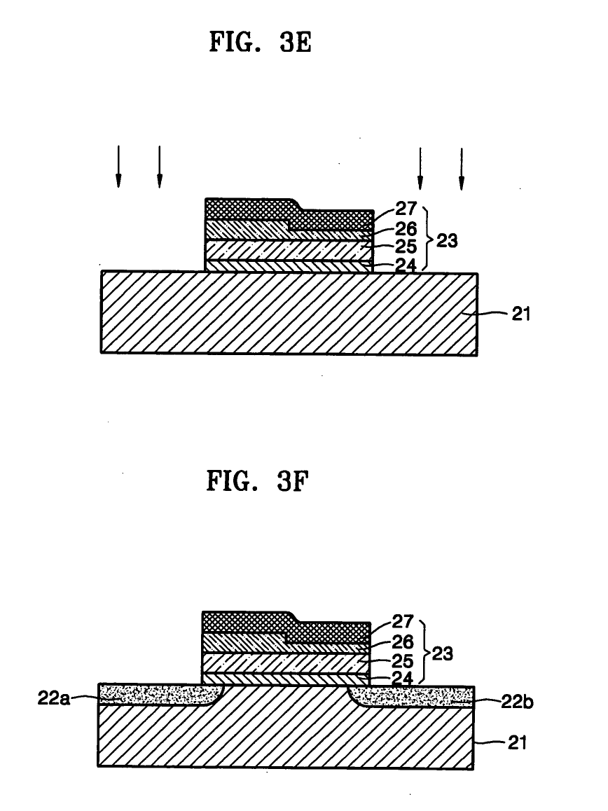

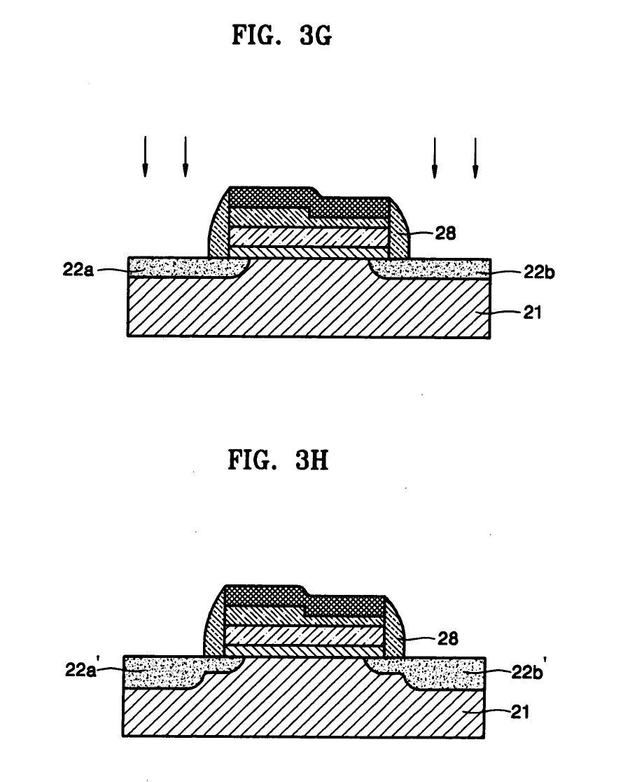

A method of manufacturing a non-volatile memory device according to an embodiment of the present invention will now be described with reference to FIGS. 3A through 3H. FIGS. 3A through 3H illustrate cross-sectional views of stages in a method of manufacturing the non-volatile memory device according to an embodiment of the present invention.

Referring to FIG. 3A, first, the semiconductor substrate 21, e.g., a p-type substrate, is prepared. The semiconductor substrate 21 may be composed of a material used in substrates of conventional memory devices, e.g., silicon.

Referring to FIG. 3B, the tunneling oxide layer 24, the floating gate 25, and the blocking oxide layer 26 are sequentially formed on the semiconductor substrate 21. These layers may be formed by chemical vapor deposition (CVD), a plasma-enhanced CVD (PECVD), low-pressure CVD (LPCVD), responsive sputtering, or the like.

Referring to FIG. 3C, one or more steps are formed in the blocking oxide layer 26 by patterning a predetermined portion of the blocking oxide layer 26. As a result of this patterning, the thickness of the blocking oxide layer 26 is not constant. Referring to FIG. 3D, a metal, a metal compound, or polysilicon is then deposited on the blocking oxide layer 26 to form the gate electrode 27.

Referring to FIG. 3E, end portions on both sides of the tunneling oxide layer 24, the floating gate 25, the blocking oxide layer 26, and the gate electrode 27 are removed by patterning to expose portions of the semiconductor substrate 21 near the edges of the semiconductor substrate 21 to form the gate structure 23. The gate structure 23 is an asymmetric gate stack structure due to the blocking oxide layer 26, which has at least one step.

Both side portions of the exposed semiconductor substrate 21 are doped with predetermined impurities, thereby forming the source 22a and the drain 22b to have a polarity opposite to the polarity of the semiconductor substrate 21. Thus, a non-volatile memory device having an asymmetric gate dielectric layer can be manufactured.

Optionally, referring to FIGS. 3G and 3H, spacers 28 may be formed on both sidewalls of the gate structure 23. The spacers 28 prevent problems that occur since the gate structure 23 has a relatively narrow width to increase the degree of integration. In other words, the spacers 28 prevent the impurities from spreading into the narrow channel region and contacting each other after formation of the source 22a and the drain 22b.

If the spacers 28 are to be formed, electric contact between the source 22a and the drain 22b is prevented by injecting low concentrations of impurities into both side portions of the semiconductor substrate 21.

Referring to FIG. 3G, the spacers 28 are formed by coating both sidewalls of the gate structure 23 with an insulating material. Referring to FIG. 3H, the non-volatile memory device is then completed by injecting high concentrations of impurities into a source 22a′ and a drain 22b′ and performing a common thermal process.

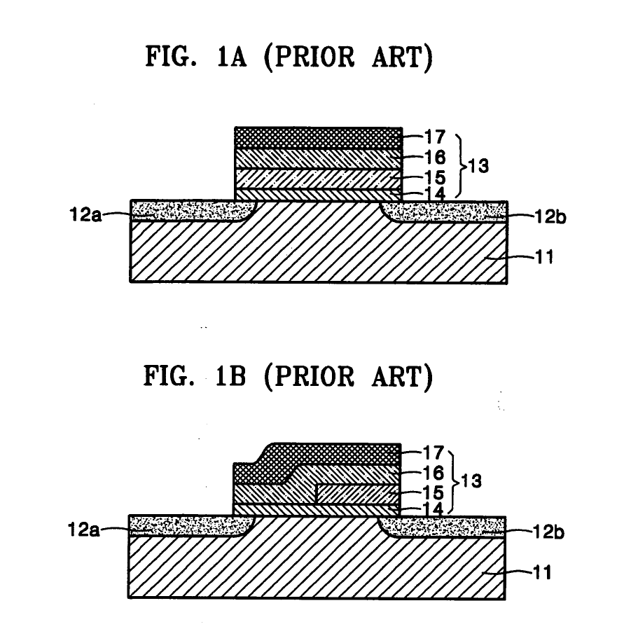

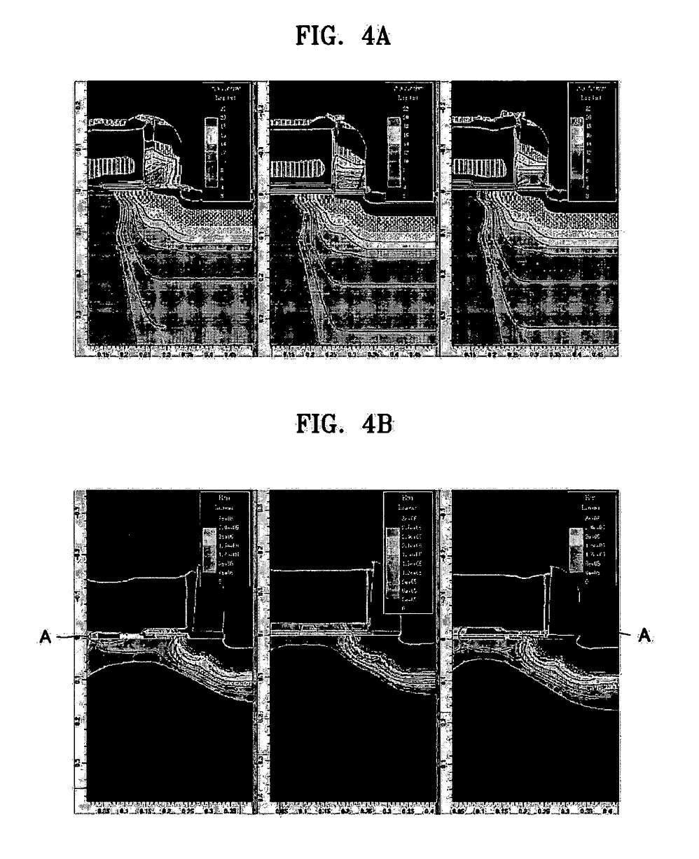

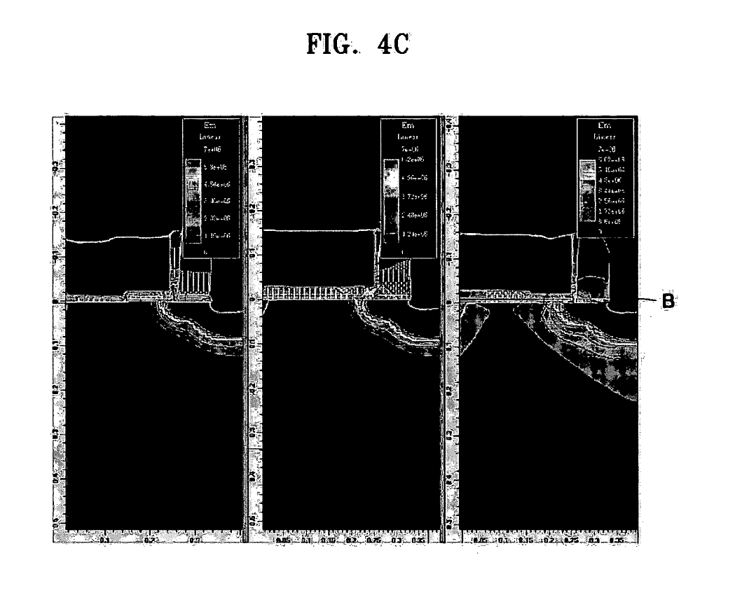

FIGS. 4A through 4C illustrate the electric features of a non-volatile memory device having an asymmetric gate dielectric layer according to an embodiment of the present invention and conventional non-volatile memory devices, i.e., the memory devices shown in FIGS. 1A and 1B.

FIG. 4A illustrates doping concentration profiles of memory devices having the structures shown in FIGS. 1B, 1A, and 2, respectively. A left image in FIG. 4A illustrates a memory device in which a portion of a floating gate 15 is eliminated, as in FIG. 1B. The three devices of FIG. 4A were all formed with identical materials. The right image is of a memory device according to an embodiment of the present invention in which the blocking oxide layer has a single step.

FIG. 4B illustrates an electron density profile when all three memory devices, i.e., as shown in FIGS. 1B, 1A and 2, respectively, store information by applying identical V_{g} and V_{d}, i.e., when trapping electrons in a trap site of floating gates 15 and 25.

In this case, the dark region of a portion A is a region in which the electron density is the highest. Comparing the memory device according to an embodiment of the present intention to the conventional SONOS memory devices, as shown in FIG. 1A, i.e., the middle image of FIG. 4B, or as shown in FIG. 1B, i.e., the left-most image of FIG. 4B, the dark portion in region A is larger in the memory device according to an embodiment of the present invention than in the conventional SONOS memory device. Therefore, when applying identical driving voltages to the memory device having an asymmetrical dielectric layer according to an embodiment of the present invention and the conventional SONOS memory device, the memory device according to an embodiment of the present invention has a greater electron injection efficiency.

FIG. 4C is a diagram illustrating an electron density profile when identical voltages are applied to all three memory devices for erasing data from the memory devices.

Referring to FIG. 4C, the electric field density in the floating gate 25 of the memory device according to an embodiment of the present invention, which is the right-most image, is greater than the electric field densities in the floating gates 15 of the conventional memory devices. That is, a dark portion B of the floating gate 25 has a large electric field density while there is almost no electric field density in the conventional memory devices, as shown in FIG. 4C.

According to the present invention, the V_{threshold} within a single memory device can be realized by forming one or more steps in a gate dielectric layer, i.e., thereby forming an asymmetric gate dielectric layer, of a semiconductor memory device. Therefore, the present invention provides a memory device having excellent ion injection efficiency and lower power consumption.

Exemplary embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A memory device, comprising:
a semiconductor substrate;
a first impurity region and a second impurity region formed by injecting impurities into the semiconductor substrate; and
a gate structure on the semiconductor substrate between the first impurity region and the second impurity region,
the gate structure comprising a gate electrode and an asymmetric dielectric layer including a floating gate.

2. The memory device as claimed in claim 1, further comprising at least two sub-channels between the first and second impurity regions.

3. The memory device as claimed in claim 1, wherein the asymmetric dielectric layer comprises:
a tunneling oxide layer on the semiconductor substrate between the first impurity region and the second impurity region;
the floating gate on the tunneling oxide layer; and
a blocking oxide layer on the floating gate.

4. The memory device as claimed in claim 3, wherein at least one of the tunneling oxide layer and the blocking oxide layer has a varying thickness.

5. The memory device as claimed in claim 4, wherein the blocking oxide layer comprises one or more steps formed therein.

6. The memory device as claimed in claim 3, wherein the tunneling oxide layer comprises silicon oxide (SiO₂).

7. The memory device as claimed in claim 3, wherein the floating gate comprises one selected from the group consisting of Si₂N₄, MO, MON, and MSiON, where M is metal.

8. The memory device as claimed in claim 7, wherein the metal is selected from the group consisting of hafnium (Hf), zirconium (Zr), tantalum (Ta), aluminum (Al) and one of the lanthanide group.

9. The memory device as claimed in claim 3, wherein the blocking oxide layer comprises one selected from the group consisting of Al₂O₃ and SiO₂.

10. The memory device as claimed in claim 3, wherein the gate electrode comprises one selected from the group consisting of polysilicon, a metal, and a metal compound.

11. The memory device as claimed in claim 1, further comprising spacers on sidewalls of the gate structure.

12. A method of manufacturing a memory device, comprising:
forming a dielectric layer asymmetrically on a semiconductor substrate;
forming a gate structure by forming a gate electrode on the dielectric layer, and removing side portions of the gate structure to expose portions of the semiconductor substrate on both sides of the gate structure; and
forming a first impurity region to one side of the gate structure and a second impurity region to another side of the gate structure by injecting impurities into the exposed semiconductor substrate.

13. The method as claimed in claim 12, wherein forming the dielectric layer comprises forming sequentially a tunneling oxide layer, a floating gate, and a blocking oxide layer on the semiconductor substrate.

14. The method as claimed in claim 13, wherein forming the tunneling oxide layer, the floating gate, and the blocking oxide layer comprises forming at least one of the tunneling oxide layer and the blocking oxide layer to have a varying thickness.

15. The method as claimed in claim 14, wherein forming the blocking oxide layer to have a varying thickness comprises forming one or more steps in the blocking oxide layer.

16. The method as claimed in claim 12, further comprising:
forming spacers on sidewalls of the gate structure; and
injecting impurities into the side portions of the semiconductor substrate, thereby forming third and fourth impurity regions having higher impurity densities than the first and second impurity regions, respectively.

17. The method as claimed in claim 12, wherein forming the dielectric layer asymmetrically comprises forming at least two sub-channels between the first and second impurity regions.
